(19) United States
(12) Patent Application Publication
(10) Pub. No.: US 2005/0133088 A1
(43) Pub. Date: Jun. 23, 2005

(54) Solar-powered water features with submersible solar cells

(75) Inventor: James P. Bologeorges, Libertyville, IL (US)

Correspondence Address: James B ologeorges General Partner;Zorba A gio Bologeorges L.P., 1203 Loyola Drive, Libertyville, IL, 60048, US

(73) Assignee: Zorba, Agio & Bologeorges, L.P., Libertyville, IL (US)

(21) Appl. No.: 10/898,606

(22) Filed: Jul. 23, 2004

Related U.S. Application Data
(60) Provisional application No. 60/531,411, filed on Dec. 19, 2003.

(51) Int. Cl. H01L 31/00

(52) U.S. Cl. 136/291; 136/244

(57) ABSTRACT

The disclosed technology can be used to implement water movement effects (e.g., water fountains) in a water feature (e.g., bird baths) by, for example, submersing one or more solar cells below a surface of the water in the water feature to convert light energy received thereby into electrical energy sufficient to directly or indirectly drive a pump (which may also, but need not, be submersible below the water surface) that provides a hydraulic pressure/suction that forms a desired water movement effect.

### RELATED APPLICATIONS

This claims priority to and the benefit of U.S. Provisional Patent Application No. 60/531,411, filed on Dec. 19, 2003, the entirety of which is incorporated herein by reference.

### TECHNICAL FIELD

The disclosed technology relates generally to water features/effects, such as water fountains incorporated into bird baths, and more particularly to water features/effects powered by submersible solar cells.

### BACKGROUND

Bird baths, ponds, swimming pools, and other types of naturally-occurring or man-made water features provide an aesthetically pleasing environment that can enhance the value of the property on which they are located by providing a more inviting area for social interaction and/or relaxation. Water fountains, waterfalls, whirlpools, wave-generating devices and/or other types of water movement effects that are incorporated into such water features can further increase their aesthetic and economic value. Unfortunately, traditional implementations of water movement effects into water features typically involve after-purchase electrical wiring and/or plumbing tasks that can significantly increase the costs of installing, maintaining, and operating the water features. Further, the additional electrical wiring and plumbing can detract from the aesthetic value of the water feature (e.g., hoses and/or wires draped along the ground) and may present trip hazards, shock hazards, and/or otherwise prove problematic. Accordingly, entities that make, purchase, maintain, and/or operate water movement effects in water features have a continuing interest in reducing the expense and complexity of such systems while concurrently improving their safety features and aesthetic appearance.

### SUMMARY

The disclosed technology can be used to implement one or more water movement effects into a water feature in a self-contained manner such that a renewable energy source (e.g., solar energy convertible to electricity using one or more solar cells, solar-charged batteries, etc.) powers one or more pumps that are instrumental in providing such water movement effects, without the complexity, expense, and/or other negative effects of additional/external electrical wiring and/or plumbing.

In one illustrative embodiment, the disclosed technology can be used to develop systems (e.g., a solar-powered water fountain in a birdbath) and perform methods in which one or more photovoltaic sources (e.g., solar cells), capable of converting light energy into electrical energy, are positioned at a desired depth (e.g., less than, equal to, or greater than about 1.5 inches) below a water surface using one or more support members and the electrical energy produced by such photovoltaic sources can provide the basis for operating a pump (by, for example, directly providing electrical energy to the pump, charging a battery that powers the pump, etc.) that forms a desired water movement effect (e.g., a spray pattern) that affects the surface of the water. The support members may include one or more flotation elements and/or be included as part of a housing (e.g., a bird bath, water fountain) that contains a body of water associated with the water surface. The entire pump or parts thereof may also be positioned below the water surface.

### BRIEF DESCRIPTION OF THE DRAWINGS

The foregoing discussion will be understood more readily from the following detailed description of the disclosed technology, when taken in conjunction with the accompanying drawings in which:

FIG. 1A schematically illustrates a cross-section of an exemplary embodiment of a water feature incorporating solar-powered water movement effects, in accordance with at least some aspects of the disclosed technology; and

FIG. 1B illustrates a 3-dimensional perspective of an exemplary embodiment of a water feature incorporating solar-powered water movement effects, in accordance with at least some aspects of the disclosed technology.

### DETAILED DESCRIPTION

Unless otherwise specified, the illustrated embodiments can be understood as providing exemplary features of varying detail of certain embodiments, and therefore, unless otherwise specified, features, components, modules, elements, and/or aspects of the illustrations can be otherwise combined, interconnected, sequenced, separated, interchanged, positioned, and/or rearranged without materially departing from the disclosed systems or methods. Additionally, the shapes and sizes of components are also exemplary and unless otherwise specified, can be altered without materially affecting or limiting the disclosed technology.

For the purposes of this disclosure, the term “substantially” can be broadly construed to indicate a precise relationship, condition, arrangement, orientation, and/or other characteristic, as well as, deviations thereof as understood by one of ordinary skill in the art, to the extent that such deviations do not materially affect the disclosed methods and systems.

In brief overview, the disclosed technology can be used to implement water movement effects in a water feature by, for example, submersing a photovoltaic source (e.g., one or more solar cells) below a surface of the water in the water feature to convert light energy received thereby into electrical energy sufficient to drive a pump (which may also, but need not, be submersible below the water surface) that provides a hydraulic pressure/suction, which forces water through a nozzle and/or other type of apparatus to form a desired water movement effect. The depth at which the solar cells can be submersed below the water surface can be selected to i) increase (relative to solar cells that are not submersed) the light-to-electric energy conversion efficiency of the solar cells by, at least in part, optically concentrating refracted and/or reflected light in the water onto the solar cells (see U.S. Pat. No. 6,583,349, the entirety of which is incorporated herein by reference), ii) improve the aesthetic appearance of the water feature by partially, if not entirely, obscuring an observer's view of the solar cells, iii) reduce the amount of debris that may otherwise obstruct the receipt of light energy by the solar cells, and/or iv) facilitate the transfer of heat from the solar cells to the surrounding water. In one particularly advantageous embodiment, the solar cells are submersed at a depth of about 1.5 inches below the water surface.

In one embodiment, the disclosed technology uses flotation elements and/or other types of dynamic or static support members to maintain a desired depth of the solar cells relative to the water surface. For example, one or more floats can be physically attached to a frame that supports the solar cells so as to maintain a desired depth regardless of changing water levels (due to, for example, adding more water to the water feature, water spills, evaporation, etc.), the solar cells can be supported by protrubances (e.g., a ledge) and/or other types of support members formed on a side and/or bottom surface of a housing of the water feature to statically maintain a particular position within the water feature, and/or in any other manner that reliably maintains a desired depth below the water surface. The support members may also serve to position the solar cells at a desired angle relative to one or more sources of light energy.

In one embodiment, the disclosed technology uses one or more water resistant or water proof connectors (made of, for example, a plastic material) to electrically and/or physically couple the solar cells to the pump and/or to the housing of the water feature so as to enable the removal of the solar cells from the water feature for repair, replacement, and/or storage.

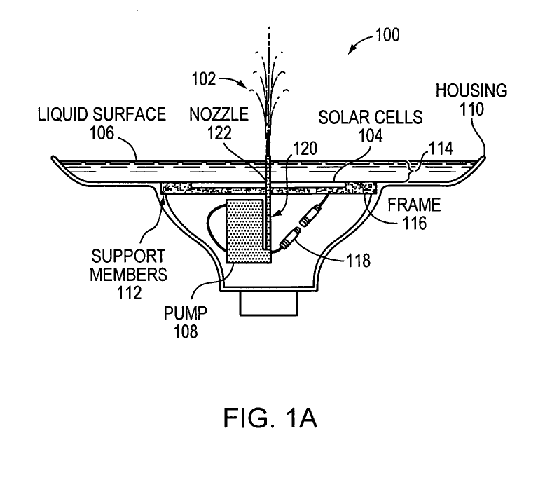

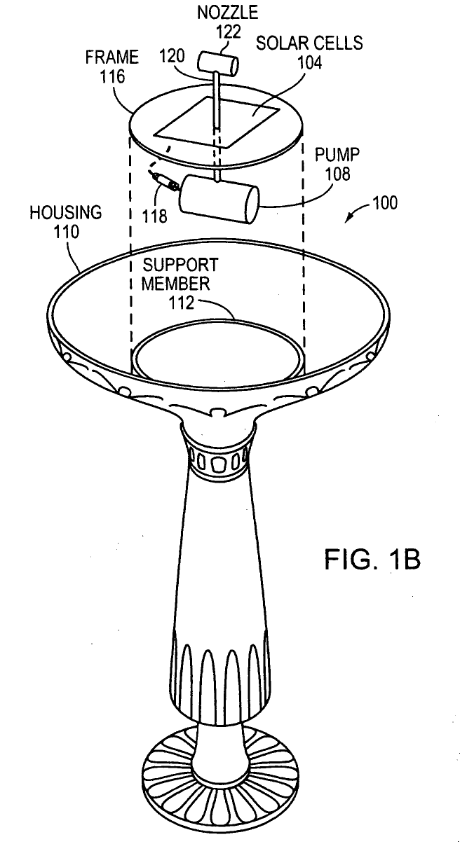

In one illustrative embodiment and with reference to FIGS. 1A and 1B, the disclosed technology can be used to develop a water feature 100 (e.g., a bird bath) exhibiting a water movement effect 102 (e.g., a water fountain) that is powered by one or more solar cells 104 submersed below a water surface 106, which provides an electric current sufficient to drive a pump 108 that is also submersed below the water surface 106. A water resistant or waterproof housing 110 (e.g., made of plastic, ceramic, etc.) of the water feature 100 can be formed into substantially any shape, such as a bird bath, pottery, floating device, and/or any other type of shape or configuration that enables the solar cells 104 to be fixedly, and preferably removably, positioned below a water surface 106. In one embodiment, the water feature's housing 110 can include protrubances, ledges, notches, indentations, and/or any other type of support member/structure 112 capable of supporting one or more solar cells 104 at a desired depth 114 below a water surface 106. The depth 114 of the solar cells 104 below the water surface 106 can be at substantially any depth that enables the solar cells 104 to receive and convert light energy to electric energy, such as at a depth up to or beyond 1.5 inches. The disclosed technology can also use a frame 116 (e.g., made of plastic) to support the solar cells 104, pump 108, and/or other elements of the water feature 100 and the frame 116 can be positioned on other support members/structures 112 of the housing 110.

In one illustrative operation, one or more solar cells 104 submersed below a water surface 106 can receive and convert light energy into electric energy and such electric energy can be provided to a pump 108 using a water-resistant or water-proof connector 118 and associated electrical wires. Upon being energized by the electric energy provided by the solar cells 104 and/or by electric energy provided by a rechargeable battery that has been charged by such solar cells 104, the pump 108 pumps water from a pump intake orifice (not shown) to a pump outlet orifice 120 that is preferably coupled to and/or is integrated with a nozzle 122 or other type of device capable of forming a desired water movement effect 102 (e.g., a desired spray pattern of a water fountain). In order to ensure a safe operation of the pump 108, the disclosed technology can also include a sensor (which may, but need not be, integrated into the pump 108) that turns the pump 108 off in response to detecting a low water or restricted flow condition and/or turns the pump 108 on in response to detecting a sufficient water level/flow condition.

Although the disclosed technology has been described with reference to specific embodiments, it is not intended that such details should be regarded as limitations upon the scope of the invention. For example, and although the disclosed technology is primarily described herein as pertaining to water, those skilled in the art will recognize that the disclosed technology can also be applied to any other type of liquid, liquid-liquid combination, liquid-solid combination (e.g., suspensions), and/or liquid-gas combination (e.g., carbonated drinks, champagne, etc.). The particular housing and/or other support structures of the water features described herein are also exemplary and a wide variety of alternatives exist, for example, in embodiments in which the solar cells are submersed below the water surface of a swimming pool and/or pond, the housing of the water feature may not exist and/or be in a form that may include flotation supporting elements that maintain a desired depth of the solar cells relative to the water surface. Further the solar cells may be integrated into at least one surface of a water feature's housing, for example, the solar cells may form at least part of the bottom and/or side surfaces of that portion of the housing that is in physical contact with the water.

1. A system for providing water movement effects, the system comprising:
at least one photovoltaic source converting light energy into electrical energy;
at least one support member in communication with the at least one photovoltaic source, the at least one support member positioning the at least one photovoltaic source at substantially a desired depth below a water surface; and
a pump in electrical communication with the at least one photovoltaic source, the pump pumping water in response to electrical energy from the at least one photovoltaic source.

2. The system of claim 1, wherein the at least one support member includes a flotation element.

3. The system of claim 1, wherein the water surface is associated with a body of water contained within a housing that includes the at least one support member.

4. The system of claim 3, wherein the housing corresponds to a bird bath.

5. The system of claim 1, wherein the desired depth below the water surface is about 1.5 inches.

6. The system of claim 1, wherein the desired depth below the water surface is less than 1.5 inches.

7. The system of claim 1, wherein the pumped water is used to form a desired water movement effect.

8. The system of claim 7, wherein the desired water movement effect corresponds to a spray pattern on the water surface.

9. The system of claim 1, wherein at least part of the pump is positioned below the water surface.

10. A fountain, comprising:
at least one photovoltaic source converting light energy into electrical energy;
a housing capable of containing a liquid, the at least one photovoltaic source being submersed to substantially a desired depth below a surface of the liquid; and
a pump being operated based on the electrical energy of the at least one photovoltaic source, the pump forming a desired liquid movement effect affecting the surface of the liquid.

11. The fountain of claim 10, wherein the liquid is water and the housing corresponds to a bird bath.

12. The system of claim 10, wherein the desired depth below the surface of the liquid is about 1.5 inches.

13. The system of claim 10, wherein the desired depth below the surface of the liquid is less than 1.5 inches.

14. The system of claim 10, wherein the desired liquid movement effect corresponds to a spray pattern on the surface of the liquid.

15. The system of claim 10, wherein at least part of the pump is positioned below the surface of the liquid.

16. A method of providing a water movement effect, the method comprising:
providing at least one photovoltaic source converting light energy into electrical energy;
positioning the at least one photovoltaic source at about a desired depth below a water surface; and
pumping water in response to the electrical energy from the at least one photovoltaic source, the pumped water forming a desired water movement effect affecting the water surface.
